(19) United States
(12) Patent Application Publication
(10) Pub. No.: US 2006/0015799 A1
(43) Pub. Date: Jan. 19, 2006

(54) Proxy-based error tracking for real-time video transmission in mobile environments

(76) Inventors: Chih-Ta Star Sung, Glonn (DE); Eckehard Steinbach, Olching (DE); Wei Tu, Munchen (DE)

Correspondence Address: CHIH-TA STAR SUNG;RM. 308, BLD. 52, NO. 195, CHUNG HSING RD., SEC. 4, CHU TUNG TOWNSHIP, HSINCHU COUNTY, 310, TW

(21) Appl. No.: 10/889,242

(22) Filed: Jul. 13, 2004

(51) Int. Cl. H03M 13/03

(52) U.S. Cl. 714/795

(57) ABSTRACT

This invention provides an efficient method of error tracking which quickly recovers the error packet of data. A side information is sent along with a normal video stream that can be used by an intermediate network node in order to improve the quality of the video transmission. The intermediate node receives the original video stream as well as the side information and uses the side information to reduce the error propagation. The error tracking is signaled from the intermediate node to the mobile phone device and the intermediate network node functions the error correction. The side information can then be used to refresh or update those areas that are affected by error concealment and error propagation.

### BACKGROUND OF THE INVENTION

1. Field of Invention

The present invention is related to digital video communication, and more specifically, to the proxy-based error tracking and correction method that results in the saving of time of error correction.

2. Description of Related Art

Digital video has been adopted in an increasing nuMacroblocker of applications, which include video telephony, videoconferencing, surveillance system, VCD (Video CD), DVD, and digital TV. In the past almost two decades, ISO and ITU have separately or jointly developed and defined some digital video compression standards including MPEG-1, MPEG-2, MPEG-4, MPEG-7, H.261, H.263 and H.264. The success of development of the video compression standards fuels the wide applications. The advantage of image and video compression techniques significantly saves the storage space and transmission time without sacrificing much of the image quality.

The popularity of internet and wireless communication coupled with the newly added error correction features so named “error resilience” in video compression standards like MPEG 4 and H.264 makes the wireless video communication feasible. Even though the technology has been significantly improved in the past decades, the wireless communication still comes across a main disadvantage of the packet data loss from about the packet loss rate ranging from 1% to 20%. This is tolerable in audio or speech communication but causes severe quality degradation in transmitting the image or video data since the error caused by the packet loss can propagate to the following video frames.

FIG. 2 shows the brief diagram of the prior art procedure of the packet loss error correction in the wireless video communication which requires round trip of data correction and causes ling delay. Most wired environment deploy high bandwidth media like an “Ethernet” with 1G to 40 G byte per second data rate in transmission, while a wireless communication channel allows only up to 10 M byte per second data. Since in the wireless mobile video communication, there is a strong iMacroblockalance between the transmission rates available in the wired (e.g. optical) and the wireless Internet (e.g. UMTS) and that the round-trip delay is mainly caused by the wired part of the connection. Statistic data shows that the majority of the packet loss is caused by the wireless link hence the prior art error correction procedure is inefficient in the round-trip delay since the requested data of error correction goes through the complete round-trip of the whole transmission and receiving route.

The present invention significantly improves the round-trip delay time by applying a different method of the wireless mobile video data error tracking and correction.

### SUMMARY OF THE INVENTION

Most prior art procedure of the packet loss error correction in wireless video communication requires long round-trip delay in correcting the data since it requires the sender re-send again the packet. The present invention is related to a method which shortens the error correction route and saves the time in the error correction.
The present invention proposes an apparatus on the sender side that generates side information to be transmitted along with an original video bitstream. The side information provides refresh or update information that can replace parts of the original bitstream referencing corrupted image areas. This side information can lead to perfect or approximate error recovery which method also improves the image quality by quickly recovering the loss packet of video data.
The present invention takes advantage of the fact that the last link of a transmission is often the bottleneck (e.g. low data rate and high error rate on wireless Internet access or mobile connection) but the round-trip time on this last link is small in comparison to the end-to-end delay between sender and receiver.
The present invention proposes an apparatus used on an intermediate network node to reconstruct the error propagation caused by lost or late data.
The present invention proposes an apparatus on the sender side that decides how much side information is sent along with the original video bitstream. The decision is made by optimizing the trade-off between the overhead introduced by sending the side information and maximization of the reconstructed video quality.
According to another eMacroblockodiment of the present invention, the side information is INTRA encoded Macroblocks of the video. The intermediate network node (e.g. base station of a mobile network) computes the current distribution of channel-induced errors and selectively replaces distorted areas of the video by inserting INTRA information from the side information.
In this eMacroblockodiment the INTRA information approximates the reconstructed Macroblock as closely as possible
According to another eMacroblockodiment the present invention, the side information is SI (H.264) Macroblocks. Here, a perfect removal of visible quality degradations due to channel-induced errors can be achieved.
According to another eMacroblockodiment the present invention, the side information is a second bit-stream that encodes Macroblocks with respect to a different reference frame. For those Macroblocks that have visible distortion, the corresponding bits in the original bitstream are replaced by the side information if the reference for these Macroblocks has been decoded without transmission induced distortion on the encoder side.
A main advantage of the present invention is fast error recovery in case of transmission errors for real-time video where retransmission of lost or late data is not possible because of hard real-time constraints. No data is retransmitted but the current error distribution is reconstructed at the intermediate node and the error is removed by using side information that has been transmitted along with the original video bitstream.
Another major advantage of the present invention is that it allows real-time video transmission from a sender to a receiver over networks where the last link is characterized by low data rate and high error rate in comparison to the rest of the network.
Another major advantage of this invention is that the amount of side information can be controlled. The side information does not have to be present for every Macroblock in the original video sequence. In this way, the amount of overhead introduced by the side information can be adapted to the transmission characteristics. The more side information is sent, the better the error recovery. If no side information is sent along with the original video stream, the invented system performs exactly as conventional real-time video transmission.

It is to be understood that both the foregoing general description and the following detailed description are by examples, and are intended to provide further explanation of the invention as claimed.

### BRIEF DESCRIPTION OF THE DRAWINGS

FIG. 1 shows three basic types of the MPEG video frame coding including I-frame, P-frame and B-frame.

FIG. 2 is a brief block diagram of a prior art wireless video communication with requesting the error correction.

FIG. 3 briefly illustrates a block diagram of the present invention of a wireless video communication.

FIG. 4 depicts details of the present invention of the error tracking and correction mechanism with sending both main and side information for error correction.

FIG. 5 illustrates the procedure of image frame packet data error tracking and correction.

FIG. 6 shows the simulated results of the image quality (in PSNR) vs. the error tracking of different frame delay.

FIG. 7 shows the simulated image quality vs. the packet loss rate.

FIG. 8 depicts the “Best QP” vs. different channel capacity

FIG. 9 illustrates the image quality improvement with present invention of the proxy-based error tracking and correction.

### DESCRIPTION OF THE PREFERRED EMACROBLOCKODIMENTS

The present invention is specifically related to the error correction of the packet data loss during the wireless mobile data transmission. The method quickly identifies the lost packet within a certain frame of video data, and requests the correction by an efficient procedure.

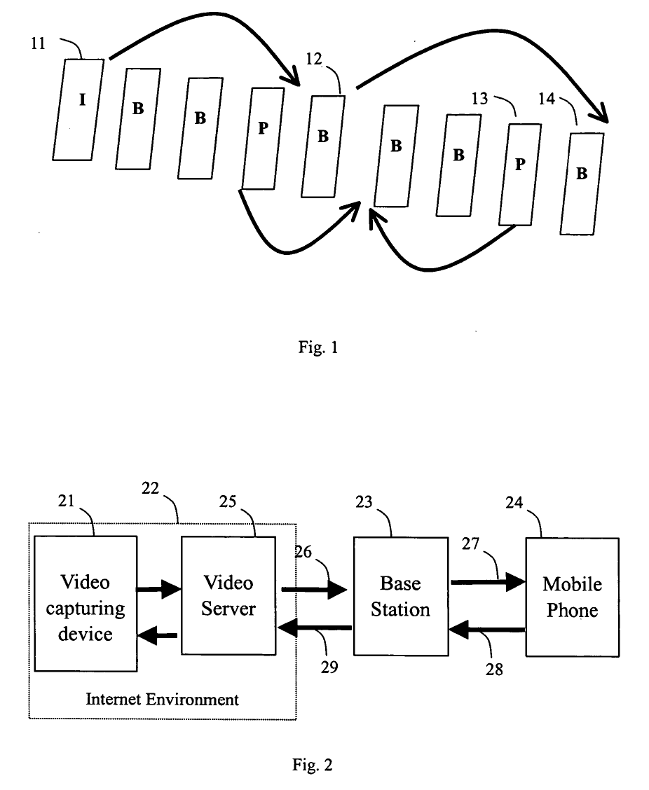

There are essentially three types of picture coding in the MPEG video compression standard as shown in FIG. 1. I-frame 11, the “Intra-coded” picture, uses the block of 8×8 pixels within the frame to code itself without referencing any other picture frame. The P-frame 12, a “Predictive” frame, uses previous I-frame or P-frame as a reference to code the differences between frames. B-frame 13, the “Bi-directional” interpolated frame, uses previous I-frame or P-frame 12 as well as the next I-frame or P-frame 14 as references to code the pixel information. In the I-frame coding, all “Block” with 8×8 pixels go through the same compression procedure that is similar to JPEG, the still image compression algorithm. Meanwhile, the P-frame and B-frame have to code the differences between the targeted frame and the reference frames. In the coding of the differences between frames, the first step is to find the difference of the targeted frame, followed by the coding of the difference. The digital video compression technique is tradeoffs among quality (accuracy), performance, and coding efficiency.

Wireless multimedia services and products have become reality due to the advent of modern communication and information technologies and the rapid growth of the consumer market. In 3G, the 3^{rd} Generation networks, video services are expected to be the most popular ones and may play the key factor in the success of 3G networks. While wireless video applications without real-time constraints (e.g. Multimedia Message Service) have been successfully introduced in the market, real-time video communication over wireless networks is still challenging. Modern video compression schemes achieve high compression ratios, but at the same time produce bit-streams that are very vulnerable against residual transmission errors at the receiver side.

Decoding of erroneous or incomplete video bit-streams leads to severe quality degradations. Because of motion-compensated prediction in P-type and B-type frame, these impairments also propagate in space and time and therefore stay visible for a significant amount of time. Hence, an error resilient transmission scheme is essential to achieve desired quality in a wireless multimedia communication system.

FIG. 2 depicts the said a prior art of commonly used error resilience of data error correction. An end user mobile phone 24 detects an error by checking the received code and requests an error correction. Error tracking is an error resilience technique that takes advantage of a back-channel 28, 29 through the base station 23 to report corrupted image areas. The encoder 21 reacts to this feedback by tracking the spatial-temporal error propagation. Those frame areas that have been identified to be corrupted are then updated by using INTRA macroblock coding. Because the update always happens in future frames to be encoded, error tracking does not introduce additional delay. Error tracking is suitable for real-time application, but the performance is closely related to the round-trip delay since the error correction takes the complete route of transmission and receiving. In the Internet 22, a video sender 25 may be located far away from the mobile station and the long trip delay leads to a serious error propagation. Larger image areas are affected and need to be refreshed, which is critical when using a low bit-rate wireless channel, as INTRA coding leads to a bit-rate increase which in term requires higher bandwidth of data transmission.

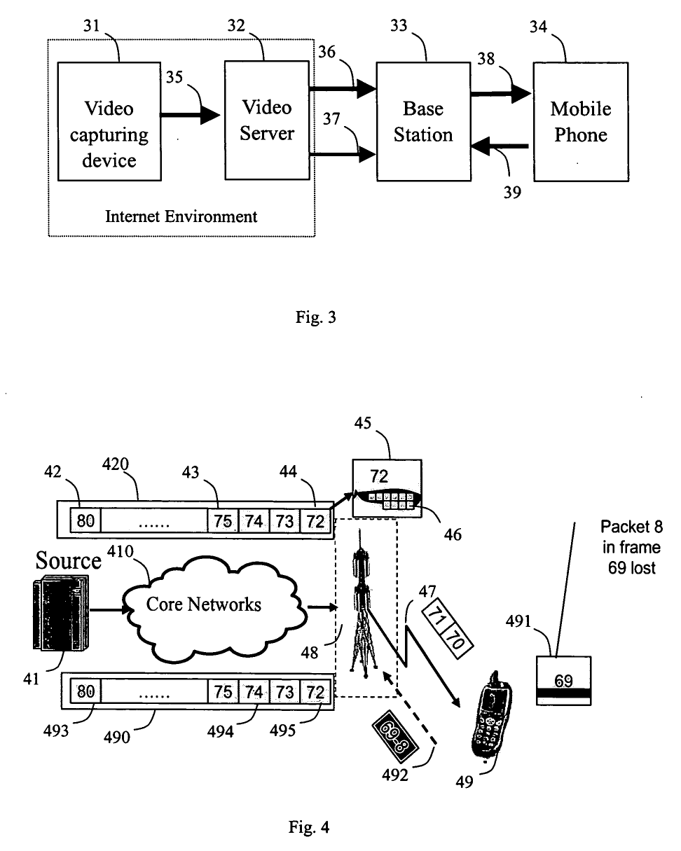

The video sender is often located in the wired Internet and the receiver is a wireless client, the round-trip time for error tracking is determined by the end-to-end delay between sender and receiver. FIG. 2 shows the conceptual solution to cope with long delays between sender and receiver would be to use the base station 33 that serves the mobile client as a proxy server and to separate the video transmission into two separate parts: a real-time video communication between the sender and the base station 26, 29, and a video communication between the base station and the mobile client 27, 28. This approach would lead to a small round-trip time for the second part and therefore good results for error tracking. The disadvantage of this approach, however, is that the base station would have to decode and re-encode the video for feedback-triggered INTRA updates. In order to avoid this heavy additional computational load on the base station one can send side information 37, along with the normal video stream 36 that can be used by the base station to perform the required INTRA updates as the concept shown in FIG. 3. The base station tracks the error propagation by parsing the bit-stream, i.e., extraction the coding mode and motion vector information, and then uses the side information 37, to perform INTRA refresh of corrupted image areas which mechanism is done in the base station 33. Starting the error recovery, a proxy can be set o a nearer position to the mobile terminal instead of doing everything at the encoder.

The base station 33 is the best position to set our error tracking proxy server as it is the interface of wired networks and wireless networks, which is also the nearest point to the mobile terminal 34. High frequency feed-back channels 38, 39 exist between the mobile terminal and base station, which enables a fast start of error tracking. Without add too much burden, INTRA macroblock update is used instead of INTRA-encode, which of course need an INTRA coded stream available at the base station. In the current or future mobile networks, the wired core networks 35 hire ATM and IP as the main technologies and provide hundred Giga bytes bandwidth, which is much larger when compared with the limited bandwidth of wireless channel (less than hundred bits). The abundant bandwidth existing in the core network makes it possible to transmit more redundant information and hence the side information. FIG. 4 illustrates the architecture of the present invention as well as the procedure of the error tracking. The error tracking is done by the proxy on the base station 48. So two video streams 420, 490 are needed to be transmitted to the base station 48, as described, one P-frame stream 42, 43, 44, and the other I-frame stream 493, 494. The downlink channel 47 between the base station and mobile station is used for the video transmission and an uplink channel is used to transmit the error messages 492. In traditional way, these error messages will also be forward back to the video sever 41, at there, error tracking is carried out. From the figure we can see in this case, the error can be somewhat recovered the earliest at frame 80, 42, 493. On the contrary, with the proxy at the base station, the error recovery will be start from frame 72, 44, 495. More macroblocks will be affected by the error propagation in this eight frame delay and which will cost more bits to recover. For instance, there are a several of packet 46 of macroblocks data included within frame 72, 45. In case of packet 8 within frame 69 is lost, the error message 69-8, 492 is sent to the proxy of the base station 48 through the down link channel 492.

Macroblock based or pixel based error tracking is used because of the following two main reasons.
In H.264 standards, Macroblocks can be even sub-partitioned into sub-blocks, which can be 16*8, 8*16, 8*8, 4*8, 8*4 and 4*4, so one Macroblock is no longer assigned one motion vector. So the basic unit for tracking should be block but not Macroblocks in the present invention.
The bandwidth of the wireless channel is limited, which means not all corrupt Macroblocks could be updated according to this bit rate limitation. Then the selection of Macroblocks is very important, pixel based error tracking can avoid over estimation of corrupted Macroblocks. At the same time, it will also provide the distorted information for all pixels in the corrupted Macroblocks, so that the severest Macroblocks can be first updated to significantly recover the quality of the stream.

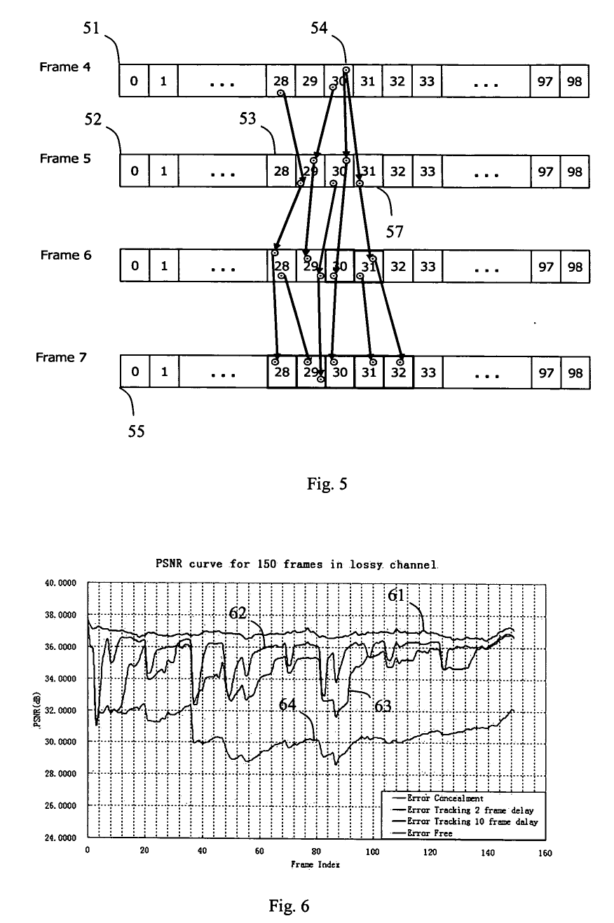

The dependencies of Macroblocks in successive frames are essential to the error tracking. The motion vectors of the MACROBLOCK produced in the motion estimation indeed provide adequate information for accurately tracing error propagation. FIG. 5 illustrates the pixel wise tracking procedure. Any pixel's motion dependency can be found by tracing back the motion vector of the block it belongs to. When the proxy receives a NAK that indicates an error occurred at MACROBLOCK 30, 54 of frame 4, 51 while the next frame to be sent is frame 7, 55. Thus, we can first trace every pixel, 53, 57 in frame 5, 52 with its motion vectors to see whether it refers to the erroneous-area in frame 4. In this step, all error pixels in frame 5 can be found and we can go on for the next frame with its own motion vectors. For this example, after 3 iterations, the erroneous MACROBLOCKs in frame 7 are worked out.

Here the forward error tracking is used instead of the backward tracking proposed in prior art method. In the wireless channel, the possible packet loss rate should bearound 10%, which means in average, at most one row of the MACROBLOCKs get lost and there are totally 9 rows of MACROBLOCKs in one frame. In the configure file of H.264 encoder, there is a parameter which is used to set the maximum length of the motion vector, default to be 16. Say in other word, if we track forward, we can know the possible affect area in the next frame, and only pixels in this area need to be checked. For example, if the second row of frame N is lost and the MV is smaller than 16, then only the MACROBLOCKs in the first, second and third rows need to be tracking in frame N+1. This will also decrease the loops in every frame. In the present invention, the delay for the NAK is assumed to be small and with forward tracking and the buffer only need to store MVs of one frame, so compared with the backward tracking, forward tracking takes more advantages in round-trip delay as well as the buffer size of saving MVs.

Packet loss in wireless channel happens randomly, so error tracking should be done iteratively with INTRA update. During this procedure, it may happen that when NAK is received and error tracking is done from frame N to frame N+2. But some MBs belong to the error propagation area maybe updated in frame N+1, caused by the errors before frame N. Then these MBs which have been updated will not used to calculate the propagation from frame N+1 to frame N+2. This is an intelligent function that can be realized on the proxy server. It can avoid over estimation and re-update and from simulation, a 0.06 dB PSNR gain can be achieved. A wireless channel is always subject to various kinds of errors. The packet error function in the simulations is modeled by a two state Markov chain. “Foreman” in QCIF resolution is used as the default sequence and 10 frame/s is selected as the frame rate. The H.264 standards reference software JM 6.1d is employed as the video codec. When we do error tracking and updating, some INTER-MBs will be replaced by INTRA-MBs, which means that additional bits are needed for the error control. We would like to reserve some bandwidth for the error control and it is set to be 80% in use and 20% reserved.

In FIG. 6, four experiments show the improvement of error tracking. The top curve 61 shows the PSNR of 36.83 dB PSNR at an average for 150 frame sequence in an error free environment. The bottom curve 64 stands for the stream suffering from a 1% packet loss. Here in H.264 codec, loop filter is hired, so some errors may fade away after several frames and the average PSNR is 30.65 dB. Here the round trip delay between the terminal and proxy server is 200 ms and the delay to the encoder is 1000 ms, presented in top and bottom curves. It is obviously that when an error happens, the 2nd curve 62 from top recovers to a good quality in a much shorter time than the third curve 63. The average PSNR of the 2^{nd} curve is 35.72 dB and of the 3^{rd} curve is 34.59 dB. Compared with the only concealment condition, the error tracking can achieve about 4 dB gain and another 1 dB gain is realized by the proxy server with its mechanism shown in above description.

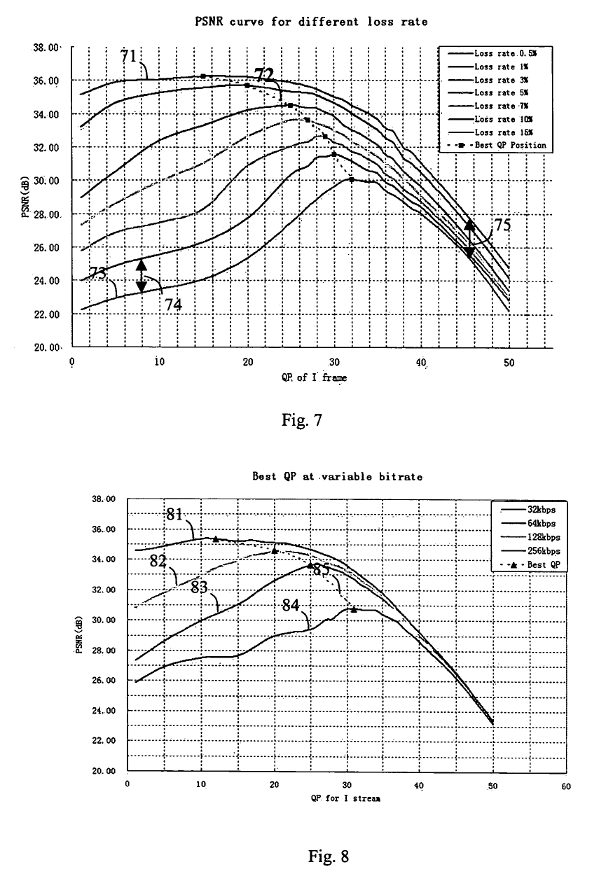

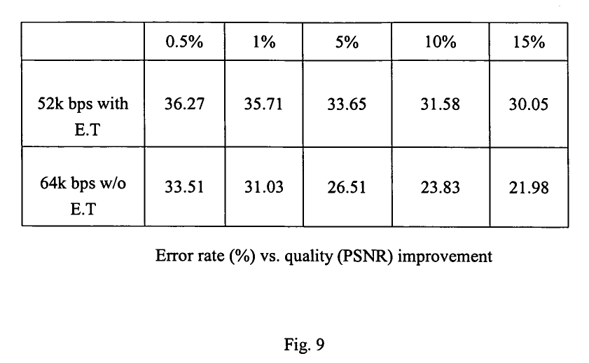

In FIG. 7, the solid curves illustrate the average PSNR depending on the QP, Quantization Parameter (which typically is kept fixed for I and P slices in order to achieve constant quality instead of constant rate) at different error rate. The larger the error rate, the more we can gain from the error tracking proxy server. When QP is small, very few MBs can be updated every frame, but there are more corrupt MBs, which results in about 2 dBs' drop 74 from one step of error rate increase. Beyond the “Best QP Position” curve, at large QP, enough MBs can be updated, so they go to very close 75 as the packet loss error can always be recovered, the decrease of PSNR between them is only caused by the number of large QP INTRA MBs used. The dot curve 72 is interpolated from the best QP points at selected loss rate. It shows that this best QP increases with the increase of channel loss rate. Having known this relationship, we can select QP according to the evaluated channel loss rate. The best QP and channel loss rate is stated, and how it changes with the available bandwidth as different bandwidth will result in different number of update MBs? In the simulation, 32 kbps, 64 kbps, 128 kbps and 256 kbps are used as target channel bandwidths. From the curves in FIG. 8, almost a same function between best QP and bandwidth can be observed. So the conclusion is that the best QP of the I-stream should be a joint function of channel bandwidth and loss rate. These are two important characters of the wireless channel, so having known the channel condition, we can have the best choice to obtain highest gain by this error tracking server.
Improvement with same bit rate in wireless channel
Here we use error tracking but keep the total bit rate less than 64 kbps. Though only 80% are used for the P-stream, but we can achieve several dB improvement compared to the case that all bandwidth is used to the P-stream and this improvement increases with the worse channel condition, a wired network bandwidth anlysis.
   Showed in the above experiments, the error tracking proxy server can give several dB improvement to the received stream quality compared with the conventional error tracking at the encoder. However, an extra stream is needed to be sent at the same time, which occupies more or less bandwidth in the core networks. Fortunately, the best quality is not contributed by the small QP. Instead, from the simulation we can find that the best QP changes from 15 to 30. In our default case, 5% error rate and 64 kbps channel 83, the best QP is 25, which means 300 kbps needed for the I-stream, not so large in the core networks. Some I-frames can be dropped when congestion happens in the core network just which will certainly sacrifice some quality. Trade off should be made between quality and bandwidth allocation.

It will be apparent to those skills in the art that various modifications and variations can be made to the structure of the present invention without departing from the scope or the spirit of the invention. In the view of the foregoing, it is intended that the present invention covers modifications and variations of this invention provided fall within the scope of the following claims and their equivalents.

What is claimed is:

1. A method for error tracking in wireless video communication comprising:
sending a main video stream to an intermediate network node;
sending a side information of video stream to the same intermediate network node; and
performing the function of the requested error correction in the intermediate network node.

2. The method of claim 1, wherein the loss of video data is signaled between the client and the intermediate node by means of feedback messages.

3. The method of claim 1, wherein the intermediate node reconstructs the current distortion distribution within the video sequence and replaces parts of the original video stream with INTRA information in order to remove those errors from the video sequence.

4. The method of claim 1, wherein one link between the intermediate network node and the mobile phone end node transmits the main data stream while another link transmits the error tracking message.

5. The method of claim 1, wherein an intermediate network node includes proxy, gateway or a base station.

6. The method of claim 1, wherein the side information is used to correct those areas that are affected by error concealment and error propagation.

7. The method of claim 1, wherein the side information consists of a second video bitstream with INTRA encoded Macroblocks.

8. The method of claim 7, wherein the sender decides how much side information is sent along with the original video bitstream.

9. The method of claim 8, wherein the decision is made by optimizing the trade-off between the overhead introduced by sending the side information and maximization of the reconstructed video quality.

10. A method of error tracking in error correction comprising:
a node of video stream is connected by a wired Internet node;
another node of video stream is connected by a wireless mobile Internet;
sending a main video stream; and
sending a side information to the same intermediate node which is a second bit-stream that encodes Macroblocks with respect to a different reference frame.

11. The method of claim 10, wherein for those Macroblocks that have visible distortion, the corresponding bits in the original bitstream are replaced by the side information if the reference for these Macroblocks has been decoded without transmission induced distortion on the encoder side.

12. The method of claim 10, wherein a high packet data loss happens in the wireless mobile Internet node, while the wired Internet node has less packet loss rate.

13. The method of claim 10, wherein the best QPs, quantization parameters of the I-frame streams are selected according to different channel condition, so that we can set the QP after the average error rate in the wireless channel is tested and the channel capacity is known.

14. The method of claim 10, wherein an error tracking proxy is set at the base station, the delay for the long round trip time in the wired network is saved and better quality can be achieved with same bitrate in the wireless channel.
